(19) United States
(12) Patent Application Publication
(10) Pub. No.: US 2026/0059649 A1
(43) Pub. Date: Feb. 26, 2026

(54) Signaling Trace with Width-Modulated Discontinuity Mitigation

(71) Applicant: Astera Labs, Inc., Santa Clara, CA (US)

(72) Inventors: Alexander Franck, West Vancouver (CA); Liang Xue, Los Altos, CA (US)

(21) Appl. No.: 18/978,647

(22) Filed: Dec. 12, 2024

Related U.S. Application Data
(60) Provisional application No. 63/687,163, filed on Aug. 26, 2024.

(51) Int. Cl. H05K 1/02; H05K 3/00

(52) U.S. Cl. CPC H05K 1/0219; H05K 3/0005; H05K 2201/09263

(57) ABSTRACT

Signaling conductors with one or more length-tuning route meanders are selectively widened within the meandered region(s) to reduce impedance discontinuity caused by trace pitch disparity.

### BRIEF DESCRIPTION OF THE DRAWINGS

The various embodiments disclosed herein are illustrated by way of example, and not by way of limitation, in the figures of the accompanying drawing and in which like reference numerals refer to similar elements and in which:

FIG. 1 illustrates an exemplary implementation of width-modulated meandered signaling traces in/on one or more layers of a printed circuit board (PCB);

FIG. 2 illustrates an exemplary sequence of operations carried out to fabricate a PCB having one or more width-modulated meanders; and

FIG. 3 illustrates exemplary operations carried out within a design-automation tool (e.g., design-automation software executed on one or more compute devices) to generate, as a design step within a manufacturing/fabrication process, a digital representation of signaling traces having one or more width-modulated meanders.

### DETAILED DESCRIPTION

In various embodiments herein, signaling traces having one or more length-tuning route meanders are selectively widened within the meandered region(s) to reduce impedance discontinuity caused by trace pitch disparity. In a number of embodiments, width-modulated trace meanders are implemented within one of the two counterpart signaling conductors of a differential signaling link—that is, within the signaling conductor, true or complement (positive or negative), having meandered routing to equalize the otherwise slightly different route distance traversed by that conductor relative to its counterpart (different lengths) in their respective spans between two endpoints. Because only one of the two signaling conductors is meandered (i.e., zig-zag routing, serpentine routing or otherwise distance-adding set of routing turns), the pitch between the paired conductors increases as the meandering conductor turns away from the non-meandered conductor, decreasing mutual impedance (i.e., decreasing mutual capacitance and/or inductance) so as to yield an undesired impedance discontinuity—a discontinuity that becomes increasingly disruptive as signaling rates push deeper into the Gigahertz range (e.g., to 26 GHz, 50 GHz, 100 GHz and beyond). By modulating the trace width of one or both conductors at the increased-pitch regions within the meander, impedance discontinuity is substantially reduced (e.g., by 100%, 200%, 300% or more; in some embodiments, for example, from approximately 3-4 ohms to less than one ohm).

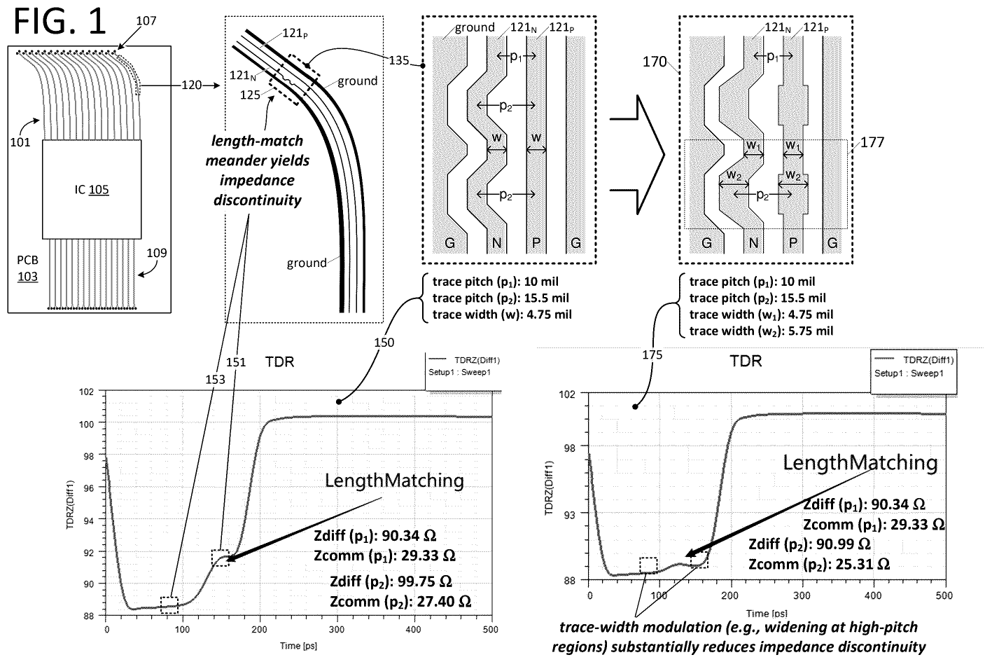

FIG. 1 illustrates an exemplary implementation of width-modulated meandered signaling traces 101 in/on one or more layers of a printed circuit board 103 (PCB), the signaling traces forming a set of differential signaling links that extend from electrical contacts of an integrated circuit component (IC or chip) to terminals 107, the latter, for example, to be conductively coupled to an electrical connector that enables PCB 103 to be removably coupled (electrically) to another circuit board (e.g., motherboard, backplane blade, etc.), signaling cable, etc. In one embodiment, PCB 103 is a paddle card to be deployed in two or more instances at respective ends of a smart cable, with each (or any one or more) instance of PCB 103 having a host-side connector coupled to terminals 107 (and thus to IC 105 via width-modulated signaling traces 101-IC 105 being, for example, a retimer IC) and a cable-side connector coupled via signaling traces 109 (any one or more or all of which may include width-modulated meanders), the latter to engage signaling conductors extending between counterpart instances of PCB 103.

An expanded view of a differential pair of signaling traces—one of multiple conductor-pair constituents of signaling traces 101—is shown at 120. In the depicted example, the two counterpart traces of the differential pair, 121_{P} and 121_{N} (bounded, for example, by ground conductors), arc toward the upper left of PCB 103, effecting a slightly longer path length on the outside conductor (121_{P}) that is compensated by length-extending (length-tuning or length-matching) routing meander in the otherwise shorter inside conductor (inside with respect to the turning radius) as shown at 125. In an oppositely directed turn (e.g., toward the upper right of PCB 103 as oriented in the drawing), conductor 121_{P} (which becomes the interior/inside conductor with respect to the rightward turn) may be implemented with a meandering route to compensate for its otherwise slightly shorter length than conductor 121_{N.}

Referring to detail view 135 of meandered region 125, the out-and-back turns (zig-zag, undulation, serpentine routing, etc.) implemented in signaling trace 121_{N} for length-matching purposes creates a spatially varying (non-uniform) pitch between the differential-signal traces (121_{N}, 121_{P}) and more specifically, an increased pitch (center-to-center distance), p₂, between the two traces as trace 121_{N} meanders away from and then runs parallel to counterpart trace 121_{P} before meandering back to nominal trace pitch/distance, p₁—that is, a single “away-and-back” meander that is repeated twice in the FIG. 1 example, but may be implemented in a single instance or more than two instances (i.e., any number of away-and-back meanders) as necessary for length matching. Also, while uniform away-and-back meanders are shown in the FIG. 1 example (e.g., both meanders extending the trace pitch to p₂), meanders may be implemented with different pitch extensions (i.e., one or more meanders within conductor 121_{N} turning further away from conductor 121_{P} than one or more others). Additionally, though shown with respect to differential conductor pairs, meanders within single-ended signaling traces may likewise yield non-uniform pitch between adjacent ground conductors and/or signal traces.

Referring to the time-domain reflectometer plot at 150, the non-uniform trace pitch effected by the routing meander (p₂=15.5 mil and thus 5 mil wider than the 10-mil nominal trace pitch, p1, in this example; “mil” referring to one-thousandth of an inch) yields an increased impedance 151 relative to the impedance 153 along the nominal-pitch segments of the trace pair (i.e., due at least to changes in mutual capacitance/mutual inductance between the 121_{N}/121_{P} trace pair at each away-and-back meander) and thus an impedance discontinuity that, while slight (e.g., 3-4 ohms), becomes increasingly limiting/disruptive at higher signaling rates, shrinking temporal and voltage signaling margins so as to limit the signaling-rate ceiling.

In the FIG. 1 embodiment, trace widths of conductors 121_{N} and 121_{P} are widened in the meandered routing segments (as shown in detail view 170) to counter the increased impedance otherwise resulting from the higher trace-pitch in those regions and thereby mitigate (reduce, render negligible or eliminate) impedance discontinuity along the signal propagation path formed by the differential conductor pair. In the depicted example, increasing widths of traces 121_{N} and 121_{P} from 4.75 mil to 5.75 mil (and thus by 1 mil) in the meandered regions equalizes the impedances within the meandered and non-meandered segments (regions, portions) of the signaling traces to within one ohm as shown in the TDR plot at 175—a trace-width modulation (selectively increasing trace widths or otherwise changing cross-sectional trace dimensions within the high-pitch meandered regions) that substantially reduces impedance discontinuity within the differential conductor pair, in this case by a factor of 3× to 4× or higher, reducing from 3-4 ohm impedance discontinuity to 1 ohm or less. In alternative embodiments, trace width modulation (i.e., increasing trace width relative to nominal trace width) may be implemented with respect to a single-ended meandering trace or a single constituent trace of a differential signaling trace-pair and/or may be implemented with higher or lower amplitude than shown in the FIG. 1 example (e.g., increasing or decreasing the difference between w2 and w1 relative to the 1-mil difference shown in FIG. 1. Likewise, the specific trace pitches/trace widths and differential impedances/common-mode impedances shown in FIG. 1 (the latter shown within the TDR plots) are presented for purposes of example only—each, any or all may be different in alternative embodiments. Moreover, while discontinuity-mitigating conductor-width modulation is shown with respect traces on a printed circuit board, trace width modulation may be implemented within an integrated circuit die and/or multi-die package, for example, to mitigate impedance discontinuity over differential or single-ended metal-layer routes, differential or single-ended polysilicon routes, and/or any other conductive signaling paths, on-die or off-die, subject to undesired impedance discontinuity. In all such cases, one or more meander layout cells 177—i.e., that may be instantiated a variable/specified number of times to define a desired number of out-and-back meanders and thus a meander effecting a desired/specified length adjustment (equalization distance) with width-modulated impedance discontinuity mitigation—may be provided as a deliverable-product data representation of a width-modulated meander and applied within a product layout tool/manufacturing process to define/produce a photomask (or other masking or feature-defining structure) which, in turn, may be used to fabricate a printed-circuit board having the specified width-modulated trace meander.

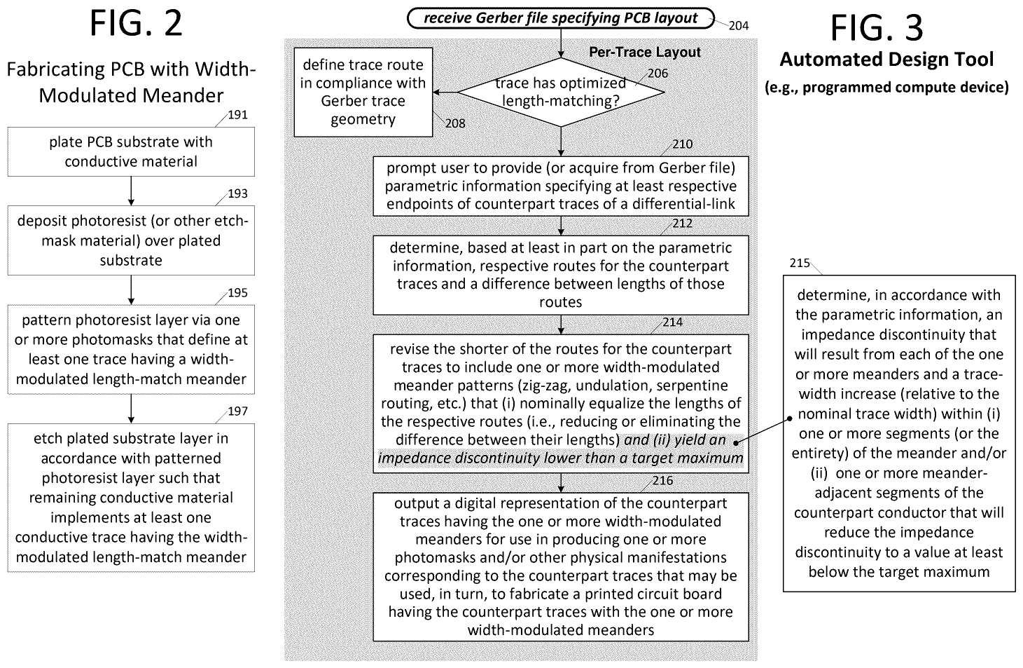

FIG. 2 illustrates an exemplary sequence of operations carried out to fabricate a printed circuit board (PCB) having one or more width-modulated meanders. At 191, a PCB substrate (e.g., glass-reinforced epoxy laminate such as FR-4—or any practicable PCB substrate) is plated with conductive material (e.g., copper, aluminum, other metals or metal alloys, or non-metal conductive materials where appropriate). Photoresist or other etch-mask material is deposited over the plated substrate (193) and then patterned (195) using one or more photomasks that define at least one trace having a width-modulated length-match meander (and in some instances two counterpart traces width-modulated in the meander region) - the patterning being effected, for example, by exposing the photoresist or other etch-mask material to violet light such that the exposed region of the photoresist may be flushed away, revealing the plating layer in accordance with the pattern. At 197, the plating layer is etched in accordance with the patterned photoresist layer such that the remaining conductive material implements at least one conductive trace having the width-modulated length-match meander. In the case of counterpart conductors of a differential pair, the patterned photoresist and etching operation my implement both the trace having the width-modulated length-match meander and a counterpart trace having one or more width-modulated segments adjacent the width-modulated length-match meander.

FIG. 3 illustrates exemplary operations carried out within a design-automation tool (e.g., design-automation software executed on one or more compute devices) to generate, as a design step within a manufacturing/fabrication process, a digital representation of signaling traces having one or more width-modulated meanders. As shown, the design-automation tool receives a printed circuit board design input at 204—for example, a Gerber-format printed circuit board design specification (i.e., “Gerber file,” including Extended Gerber or X-Gerber or X2-Gerber in accordance with RS-274X or RS-274X2) or any other practicable design input data describing, for example and without limitation, one or more printed circuit board images, copper layers, solder masks, legends, drill/via data, etc. Where one or more layers, masks, images etc. of the design input specify single-ended or differential traces that do not require optimized trace-length matching (i.e., no meander/serpentine routing and thus negative determination at 206), the design tool defines the trace route in compliance with pre-established geometry in accordance with the design input (e.g., Gerber trace geometry) at 208. By contrast, where the design input specifies automated routing of counterpart traces of a differential signaling link with optimized length-matching (affirmative determination at 206), the design tool either (i) prompts a user/operator of the design tool to provide parametric information specifying at least respective endpoints of the counterpart traces and nominal trace widths or (ii) obtains the parametric information from the design (e.g., from an extension of the design input file) as shown at 210. At 212, the design-automation tool determines, based at least in part on the parametric information, respective routes for the counterpart traces and a difference between lengths of those routes (212), revising the shorter of the counterpart routes to include one or more width-modulated meander patterns (214) that both nominally equalize the lengths of the counterpart routes and yield an estimated, simulated and/or actual impedance discontinuity within a predetermined tolerance (e.g., less than a target maximum which may be specified by the user, for instance, as part of the parametric information). In one embodiment, the automated-design tool meets the impedance discontinuity target (i.e., impedance discontinuity less than target) as shown at 215—determining, in accordance with the user-supplied parametric information, an impedance discontinuity that will result from each of the one or more meanders and a trace-width increase (relative to the nominal trace width that, when applied within one or more segments (or the entirety) of the meander and/or one or more meander-adjacent segments of the counterpart conductor that will reduce the impedance discontinuity to a value at least below the target maximum. In a number of embodiments, for example, the parametric information may specify both the nominal trace width and a maximum trace width (and also an expanded pitch at the meander region), with the design-automation tool expanding the trace widths of one or more segments of the counterpart conductors (in the meander region) as necessary—and up to the user-specified maximum width—to achieve a projected/estimated within-tolerance impedance discontinuity. In some applications, for instance, the design-automation tool may determine longer or shorter runs of widened trace regions (and also widen trace widths—greater than nominal up to the specified maximum—along all or part of those runs) as necessary to achieve a simulated impedance discontinuity below the target maximum. Also, while explained with respect to routing of one counterpart pair of traces, the design tool may automate (or assist in determining) layout for multiple such pairs of traces (and/or single-ended traces, etc.) in a unified set of computations/calculations that account for, as an example, the number routes and circuit board area (including multi-layer area) available for such routes.

After determining layouts for the width-modulated meanders (collectively in operations 210, 212, 214), the automation-design tool outputs a digital representation of the counterpart traces (i.e., having the one or more width-modulated meanders) for use in producing one or more photomasks and/or other physical manifestations corresponding to the counterpart traces (216) that may be used, in turn, to fabricate a printed circuit board having the counterpart traces (with the one or more width-modulated meanders) disposed on one or more layers thereof.

In the foregoing description and in the accompanying drawings, specific terminology and drawing symbols have been set forth to provide a thorough understanding of the disclosed embodiments. In some instances, the terminology and symbols may imply specific details not required to practice those embodiments. For example, the various trace pitches, trace dimensions, impedances, routing layouts, circuit implementations and so forth are provided for purposes of example only—any practicable alternatives may be implemented in all cases. Signals and signaling links, however shown or described, can be single-ended or differential. The term “coupled” is used herein to express a direct connection as well as a connection through one or more intervening circuits or structures. The terms “exemplary” and “embodiment” are used to express an example, not a preference or requirement. Also, the terms “may” and “can” are used interchangeably to denote optional (permissible) subject matter. The absence of either term should not be construed as meaning that a given feature or technique is required.

Various modifications and changes can be made to the embodiments presented herein without departing from the broader spirit and scope of the disclosure. For example, features or aspects of any of the embodiments can be applied in combination with any other of the embodiments or in place of counterpart features or aspects thereof. Accordingly, the specification and drawings are to be regarded in an illustrative rather than a restrictive sense.

What is claimed is:

1. An electrical apparatus comprising:
a first signaling conductor;
a second signaling conductor routed alongside the first signaling conductor with a nominal pitch and having:
a nominal cross-sectional dimension; and
one or more meander regions in which the second signaling conductor (i) is routed away from and then back toward the first signaling conductor so as to effect, in each of the one or meandered regions, a respective pitch different from the nominal pitch, and (ii) has a cross-sectional dimension altered relative to the nominal cross-sectional dimension to mitigate impedance discontinuity due to the respective pitch different from the nominal pitch.

2. The electrical apparatus of claim 1 further comprising a printed circuit board and wherein the first and second signaling conductors comprise first and second signaling traces disposed on one or more substrate layers of the printed circuit board.

3. The electrical apparatus of claim 2 further comprising an integrated circuit device disposed on the printed circuit board and having one or more integrated circuit dies and wherein the first and second signaling traces are electrically coupled to respective electrical contacts of the one or more integrated circuit dies.

4. The electrical apparatus of claim 1 wherein the first and second signaling conductors are sandwiched between ground conductors.

5. The electrical apparatus of claim 1 wherein the first and second signaling conductors are routed between respective first and second pairs of endpoints such that, but for the one or more meander regions in the second signaling conductor, the route of the first signaling conductor between the first pair of endpoints would be longer than the route of the second signaling conductor between the second pair of endpoints.

6. The electrical apparatus of claim 1 wherein the one or more meander regions in the second signaling conductor nominally equalize otherwise disparate route-lengths of the first and second signaling conductors.

7. The electrical apparatus of claim 1 wherein at least one of the one or more meander regions comprises a routing of the second signaling conductor away from the first signaling conductor by a first distance, nominally parallel to the first signaling conductor at the first distance, and then back toward the first signaling conductor, and wherein a sum of the first distance and the nominal pitch constitutes the respective pitch different from the first pitch.

8. The electrical apparatus of claim 1 wherein the first and second signaling conductors comprise first and second signaling traces and wherein the cross-sectional dimension altered relative to the nominal cross-sectional dimension comprises trace width.

9. The electrical apparatus of claim 1 wherein the cross-sectional dimension altered relative to the nominal cross-sectional dimension to mitigate impedance discontinuity due to the respective pitch different from the nominal pitch comprises a cross-sectional dimension altered sufficiently relative to the nominal cross-sectional dimension to reduce the impedance discontinuity by at least a factor of two.

10. The electrical apparatus of claim 1 wherein the cross-sectional dimension altered relative to the nominal cross-sectional dimension to mitigate impedance discontinuity due to the respective pitch different from the nominal pitch comprises a cross-sectional dimension altered sufficiently relative to the nominal cross-sectional dimension to reduce the impedance discontinuity below one ohm.

11. A method, executed within a computing device, for generating a digital representation of a physical layout of signaling traces on a printed circuit board, the method comprising:
receiving, within the computing device, information that specifies a printed circuit board layout, including parametric information specifying respective endpoints of counterpart first and second signaling traces of a differential signaling link;
determining, based at least in part on the parametric information, respective routes for the first and second signaling traces and a nonzero difference between lengths of the first and second signaling traces when laid out along those respective routes; and
adjusting the route of the first signaling trace to include one or more meander regions in which the first signaling trace (i) turns away from and then back toward the second signaling conductor so as to effect, in each of the one or meandered regions, a respective pitch different from a nominal pitch between the first and second signaling traces, and (ii) has a cross-sectional dimension altered relative to a nominal cross-sectional dimension of the first signaling trace to mitigate impedance discontinuity due to the respective pitch different from the nominal pitch.

12. The method of claim 11 wherein receiving information that specifies the printed circuit board layout comprises receiving an electronic file that specifies the printed circuit board layout.

13. The method of claim 11 wherein receiving the electronic file comprises receiving a Gerber file.

14. The method of claim 11 wherein receiving the information that specifies the printed circuit board layout including the parametric information comprises receiving (i) an electronic Gerber file that specifies at least part of the printed circuit board layout, and (ii) user input that includes the parametric information specifying respective endpoints of the counterpart first and second signaling traces.

15. The method of claim 11 wherein determining respective routes for the first and second signaling traces comprises determining respective routes for the first and second signaling traces along on one or more substrate layers of the printed circuit board.

16. The method of claim 15 wherein determining respective routes for the first and second signaling traces along on one or more substrate layers of the printed circuit board comprises determining respective routes for the first and second signaling traces that extend from respective points of electrical contact with an integrated circuit component to be mounted to the printed circuit board.

17. The method of claim 11 wherein determining the respective routes for the first and second signaling traces comprises determining respective routes for the first and second signaling traces that run between ground conductors.

18. The method of claim 11 wherein determining the respective routes for the first and second signaling traces comprises determining respective routes for the first and second signaling traces that run between respective first and second pairs of endpoints such that, but for the one or more meander regions in the first signaling trace, the route of the first signaling trace between the first pair of endpoints would be shorter than the route of the second signaling traces between the second pair of endpoints.

19. The method of claim 11 wherein the cross-sectional dimension altered relative to the nominal cross-sectional dimension to mitigate impedance discontinuity due to the respective pitch different from the nominal pitch comprises a cross-sectional dimension altered sufficiently relative to the nominal cross-sectional dimension to reduce the impedance discontinuity by at least a factor of two.

20. The method of claim 11 wherein the cross-sectional dimension altered relative to the nominal cross-sectional dimension to mitigate impedance discontinuity due to the respective pitch different from the nominal pitch comprises a cross-sectional dimension altered sufficiently relative to the nominal cross-sectional dimension to reduce the impedance discontinuity below one ohm.
